(19) United States
(12) Patent Application Publication
(10) Pub. No.: US 2018/0175321 A1
(43) Pub. Date: Jun. 21, 2018

(54) TRANSPARENT ORGANIC LIGHT EMITTING DIODE AND METHOD FOR MANUFACTURING THE SAME

(71) Applicant: WISECHIP SEMICONDUCTOR INC., Miaoli Country (TW)

(72) Inventors: Chih-Hsien Yuan, Jhunan Township (TW); I-Hsuan Lin, Jhunan Township (TW); Chien-Le Li, Jhunan Township (TW); Yung-Cheng Tsai, Jhunan Township (TW); Chien-Hsun Chen, Jhunan Township (TW)

(21) Appl. No.: 15/841,451

(22) Filed: Dec. 14, 2017

(30) Foreign Application Priority Data
Dec. 16, 2016 (TW) 105219225

(51) Int. Cl. H01L 51/52; H01L 27/32; H01L 51/56

(52) U.S. Cl. CPC H01L 51/5221; H01L 51/56; H01L 27/3283; H01L 27/3246

(57) ABSTRACT

A transparent organic light emitting diode (OLED) includes a transparent substrate; transparent anodes on the transparent substrate and bridged by an insulating layer; at least an isolation pillar provided above the insulating layer; an organic light emitting layer coated on the surfaces of the transparent anodes and the isolation pillars; and a metal cathode coated on the surfaces of the organic light emitting layer on the transparent anodes. When light passes through the transparent OLED, only the areas where the metal cathode is coated will affect the light transmittance, and the rest of the areas not coated with the metal cathode may maintain a better transmittance. By reducing the coating area of the metal cathode, the transparent OLED is able to increase its transmittance accordingly.

### BACKGROUND

### 1. Technical Field

The present disclosure relates to transparent organic light emitting diodes (OLEDs), and, more particularly, to a transparent OLED and a method for manufacturing the same.

### 2. Description of Related Art

With the increasing demands for electronic products and the improvements in lighting application technology, organic light-emitting diodes (OLEDs) technology is developing rapidly. Display devices or lighting fixtures using OLEDs, having the advantages of self-luminescent, fast response, high color saturation etc., coupled with simple processes and lower costs, have gradually become the mainstream on the market.

Among these, transparent OLEDs are able to achieve transparent display without the need for backlights. The light emitting principle behind this is a glass substrate, used as the base, being sequentially provided with a transparent electrode (ITO; anode), an organic light emitting layer and a metal electrode (cathode) thereon; when power is supplied to the transparent electrode and the metal electrode at an appropriate voltage, holes from the anode and electrons from the cathode are combined in the organic light emitting layer to produce photons, which may produce primary colors such as red, green and blue, depending on the materials of the organic light emitting layer used. Therefore, this type of transparent OLED in which the light source capable of passing through the transparent electrode or the metal electrode can be applied to smart handheld devices (such as transparent mobile phones or tablets), display windows (such as jewelry display cabinets, refrigerators, department store windows), cars (such as transparent display car windows), advertising billboards and many other fields. Currently, this new type of transparent OLEDs has become a main research area driven by the large market demands in the foreseeable future.

Referring to FIGS. 1 and 2, a cross-sectional planar view and a top planar view depicting a transparent display of the prior art are shown. An insulating layer 2 made of polyimide (PI) is interposed between anodes (ITO) 1. Isolation pillars 3 are then provided on the insulating layer 2. An organic layer 4 and a cathode 5 are sequentially vapor deposited on the anodes 1 by means of vacuum deposition using a pre-defined metal mask. The organic layer 4 and the cathode 5 are vapor-deposited in a full-screen manner as shown in FIG. 2. The cathode 5 is broken by the isolation pillars 3 to avoid short circuit of the cathode 5. Cathode 5 is generally made of a low work function material, such as Mg/Ag (alloy), ytterbium (Yb), gallium (Ga), barium (Ba), Mg/Al (alloy), etc., in order to address compatibility issue. However, the transmittance of these low work function materials is generally very poor, as compared with the transparent conductive film, such as the anodes 1. As a result, when light is emitted from a light source, the transmittance is adversely affected by the cathode 5 on the surfaces of the isolation pillars 3 and the organic layer 4, thus reducing the transmittance of the overall transparent display.

To this end, there is a need in the industry for an improvement on the low transmittance of the conventional transparent OLED due to the metal cathode.

### SUMMARY

The present disclosure provides a transparent organic light emitting diode (OLED), in which a metal cathode is coated only on the surface of an organic light emitting layer on transparent anodes but not the remaining areas to reduce the coating area of the metal cathode and improve the light transmittance.

In order to achieve the above and other objectives, the present disclosure provides a transparent organic light emitting diode (OLED), which may include: a transparent substrate; transparent anodes arranged at an interval on the transparent substrate and bridged by an insulating layer; at least an isolation pillar provided above the insulating layer; an organic light emitting layer coated on the surfaces of the transparent anodes and the isolation pillars; and a metal cathode coated on the surface of the organic light emitting layer on the transparent anodes. When light passes through the transparent OLED, only the areas where the metal cathode is coated will affect the light transmittance, and the rest of the areas not coated with the metal cathode may maintain a better transmittance. By reducing the coating area of the metal cathode, the transparent OLED is able to increase its transmittance accordingly.

In one embodiment, the insulating layer and the isolation pillars are made of transparent or semi-transparent resins.

The present disclosure further provides a method for manufacturing a transparent OLED, which may include: providing a transparent substrate; forming transparent anodes at an interval on the transparent substrate; forming an insulating layer between the transparent anodes; disposing at least an isolation pillar above the insulating layer; forming an organic light emitting layer on the surfaces of the transparent anodes and the isolation pillars; and coating a metal cathode on the surface of the organic light emitting layer on the transparent anodes by using a mask.

The present disclosure further provides another method for manufacturing a transparent OLED, which may include: providing a transparent substrate; forming transparent anodes at an interval on the transparent substrate; forming an insulating layer between the transparent anodes; disposing at least an isolation pillar above the insulating layer; forming an organic light emitting layer on the surfaces of the transparent anodes and the isolation pillars; coating a metal cathode on the surface of the organic light emitting layer on the transparent anodes and on the surfaces of the isolation pillars; and removing the isolation pillars.

The present disclosure further provides another method for manufacturing a transparent OLED, which may include: providing a transparent substrate; forming transparent anodes at an interval on the transparent substrate; forming an insulating layer between the transparent anodes; forming an organic light emitting layer on the transparent anodes; and coating a metal cathode on the surface of the organic light emitting layer on the transparent anodes by using a mask.

### BRIEF DESCRIPTION OF THE DRAWINGS

The present disclosure can be more fully understood by reading the following detailed description of the embodiments, with reference made to the accompanying drawings, wherein:

FIG. 1 is a cross-sectional planar view of a conventional transparent OLED along line X-X in FIG. 2;

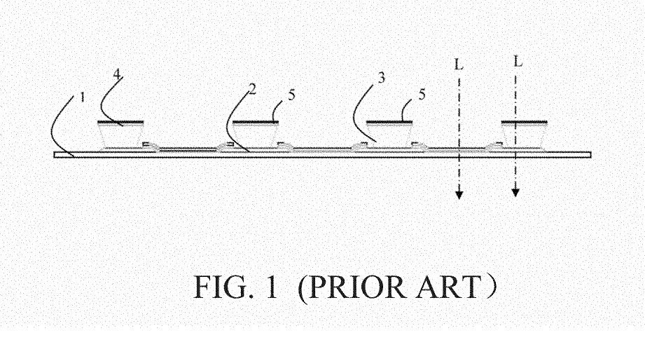

FIG. 2 is a top view of the conventional transparent OLED in FIG. 1;

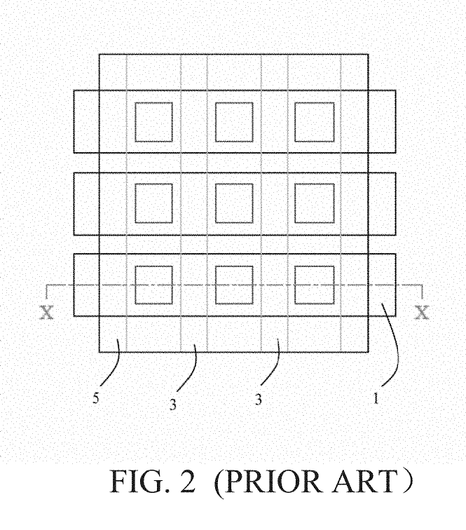

FIG. 3 is a cross-sectional planar view of a transparent OLED along line X-X in FIG. 4 in accordance with a first embodiment of the present disclosure;

FIG. 4 is a top view of the transparent OLED in FIG. 3;

FIG. 5 is a cross-sectional planar view of a transparent OLED in accordance with a second embodiment of the present disclosure;

FIG. 6 is a flowchart illustrating a method for manufacturing a transparent OLED in accordance with an embodiment of the present disclosure;

FIG. 7 is a schematic diagram depicting forming a transparent OLED by using a mask in accordance with the present disclosure;

FIG. 8 is a flowchart illustrating a method for manufacturing a transparent OLED in accordance with another embodiment of the present disclosure; and

FIG. 9 is a schematic diagram depicting forming a transparent OLED by removing isolation pillars in accordance with the present disclosure.

### DETAILED DESCRIPTION OF THE EMBODIMENTS

The following illustrative embodiments are provided to illustrate the disclosure of the present disclosure, these and other advantages and effects can be apparently understood by those in the art after reading the disclosure of this specification. The present disclosure can also be performed or applied by other different embodiments. The details of the specification may be on the basis of different points and applications, and numerous modifications and variations can be devised without departing from the spirit of the present disclosure.

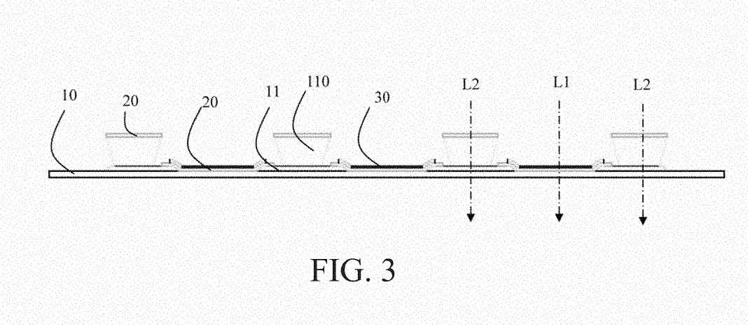

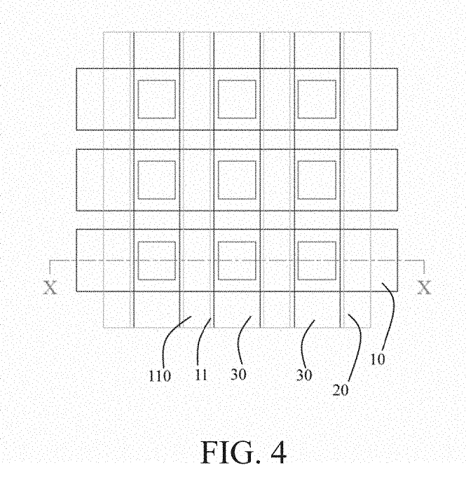

Referring to FIGS. 3 and 4, a cross-sectional planar view and a top planar view depicting a transparent organic light-emitting diode (OLED) in accordance with a first embodiment of the present disclosure are shown. The transparent OLED of this embodiment includes: a transparent substrate (not shown), transparent anodes 10, an organic light emitting layer 20, and a metal cathode 30.

The transparent anodes (e.g., Indium Tin Oxide (ITO)) 10 are arranged at an interval on the transparent substrate and bridged by an insulating layer made of a transparent or semi-transparent resin, such as polyimide (PI) 11. Isolation pillars 110 made of transparent or semi-transparent resin are then provided above the insulating layer 11.

In the first embodiment, the insulating layer 11 and the isolation pillars 110 can be made of a transparent resin including poly methyl methacrylate (PMMA), polycarbonate (PC), polystyrene (PS), or polyethylene terephthalate (PET or PETE) having a transmittance of 80% or more for visible light having wavelengths in the range from 400 nm to 800 nm, or a semi-transparent resin including polypropylene (PP) or polyamide (PA) having a transmittance between 50%-85% for visible light having wavelengths in the range from 400 nm to 800 nm.

The organic light emitting layer 20 is coated on the surfaces of the transparent anodes 10 and the isolation pillars 110.

The metal cathode 30, which can be made of a metal material, is coated on the surface of the organic light emitting layer 20 on the transparent anodes 10.

As shown in FIG. 3, the ideal transmittances of a first light source L1 and a second light source L2 are 85%. However, as the metal material of the metal cathode 30 is not completely transparent, the transmittance of the first light source L1 passing through the organic light emitting layer 20 on the transparent anode 10 is reduced to about 60% from 85% due to the coating of the metal cathode 30 on a portion of the organic light emitting layer 20. On the other hand, the transmittance of the second light source L2 passing through the remaining portion of the organic light emitting layer 20 is maintained at around 85% since the surface of the organic light emitting layer 20 in the portion is not coated with the metal cathode 30.

In existing transparent OLEDs, since the isolation pillars 110 are provided between the transparent anodes 10, the isolation pillars 110 occupy a considerable amount of area of a transparent OLED. If a full-screen coating of the metal cathode is used, as is the case in the prior art, in which the surfaces of both the organic light emitting layer and the isolation pillars are coated with the metal cathode, transmittance of light passing through the areas of the transparent anodes 10 and the isolation pillars 110 will be reduced due to the presence of the metal cathode 30.

On the contrary, in the transparent OLED in accordance with the first embodiment of the present disclosure, the metal cathode 30 is only provided on the surface of the organic light emitting layer 20 on the transparent anodes 10, not on the surface of the organic light emitting layer 20 on the isolation pillars 110. Therefore, the transmittance of the transparent OLED according to the present disclosure, when compared with that of the conventional transparent OLED, is only affected where the first light source L1 is passing through the surface of the organic light emitting layer 20 on the transparent anodes 10 on which the metal cathode 30 is provided, and the second light source L2 is capable of maintaining a better transmittance. In general, the overall transmittance of the transparent OLED is greatly improved by reducing the coating area of the metal cathode 30.

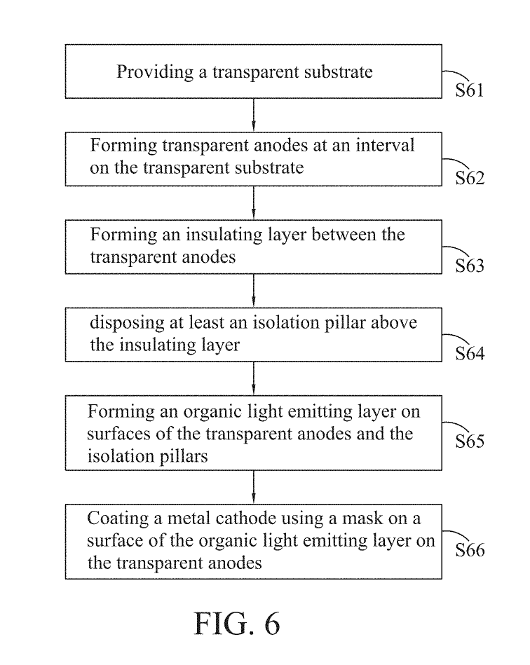

Referring to FIG. 6, a flowchart illustrating a method for manufacturing a transparent OLED in accordance with an embodiment of the present disclosure is shown. The method for manufacturing a transparent OLED includes the following steps. In step S61, a transparent substrate is provided. In step S62, transparent anodes are arranged at an interval on the transparent substrate. In step S63, an insulating layer is formed between the transparent anodes. In step S64, isolation pillars are disposed above the insulating layer. In step S65, an organic light emitting layer is formed on the surfaces of the transparent anodes and the isolation pillars. In step S66, a metal cathode is coated using a mask on the surface of the organic light emitting layer on the transparent anodes.

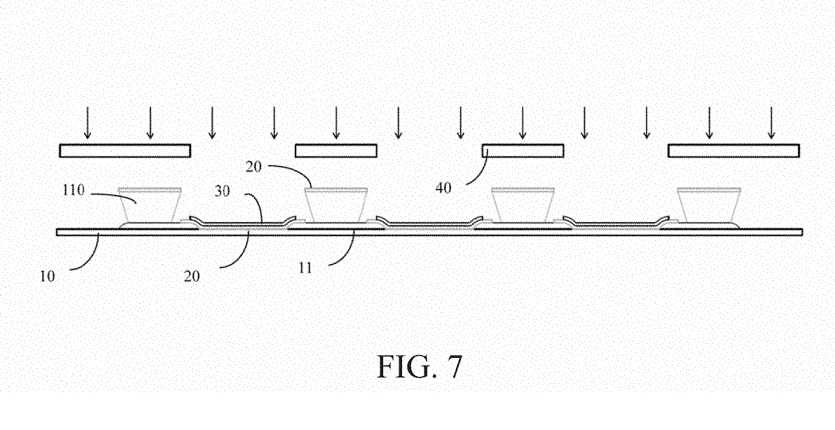

As shown in FIG. 7, in order for the metal cathode 30 not to be formed on the isolation pillars 110 and affect the transmittance, a mask 40 is used to restrict where the metal cathode 30 is to be formed when coating the metal cathode 30 such that the metal cathode 30 is only formed on the surface of the organic light emitting layer 20 on the transparent anodes 10.

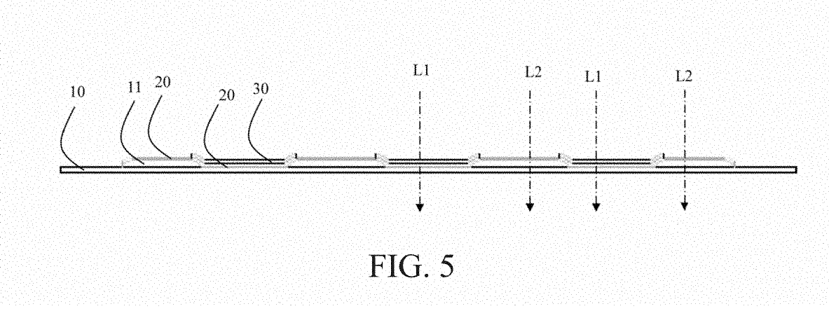

Moreover, referring to FIG. 5, a cross-sectional planar view depicting a transparent OLED in accordance with a second embodiment of the present disclosure is shown. The transparent OLED of this embodiment includes: a transparent substrate (not shown), transparent anodes 10, an organic light emitting layer 20, and a metal cathode 30.

The transparent anodes (e.g., ITO) 10 are arranged at an interval on the transparent substrate and bridged by an insulating layer made of transparent or semi-transparent resin such as polyimide (PI) 11.

In the second embodiment, the insulating layer 11 can be made of a transparent resin including poly methyl methacrylate (PMMA), polycarbonate (PC), polystyrene (PS), or polyethylene terephthalate (PET or PETE) having a transmittance of 80% or more for visible light having wavelengths in the range from 400 nm to 800 nm, or a semi-transparent resin including polypropylene (PP) or polyamide (PA) having a transmittance between 50%-85% for visible light having wavelengths in the range from 400 nm to 800 nm.

The organic light emitting layer 20 is coated on the surfaces of the transparent anodes 10.

The metal cathode 30, which can be made of a metal material, is coated on the surface of the organic light emitting layer 20 on the transparent anodes 10.

As shown in FIG. 5, the ideal transmittances of a first light source L1 and a second light source L2 are 85%. However, as the metal material of the metal cathode 30 is not completely transparent, the transmittance of the first light source L1 passing through the organic light emitting layer 20 on the transparent anode 10 is reduced to about 60% from 85% due to the metal cathode 30 coated on portions of the organic light emitting layer 20. On the other hand, the transmittance of the second light source L2 passing through the remaining portions of the organic light emitting layer 20 is maintained at around 85% since the surface of the organic light emitting layer 20 in these portions is not coated with the metal cathode 30.

In the transparent OLED in accordance with the second embodiment of the present disclosure, the metal cathode 30 is only provided on the surface of the organic light emitting layer 20 on the transparent anodes 10. Therefore, the transmittance of the transparent OLED according to the present disclosure, when compared with that of the conventional transparent OLED, is only affected where the first light source L1 is passing through the surface of the organic light emitting layer 20 on the transparent anodes 10 on which the metal cathode 30 is provided, and the second light source L2 is capable of maintaining a better transmittance.

In summary, the difference between the second embodiment and the first embodiment is that the second embodiment lacks the isolation pillars 110. However, in the first and the second embodiments, the same technical feature exists, in which the metal cathode 30 in only coated on the surface of the organic light emitting layer 20 on the transparent anodes 10, but not on the remaining areas. By reducing the coating area of the metal cathode 30, the transmittance of light can be increased.

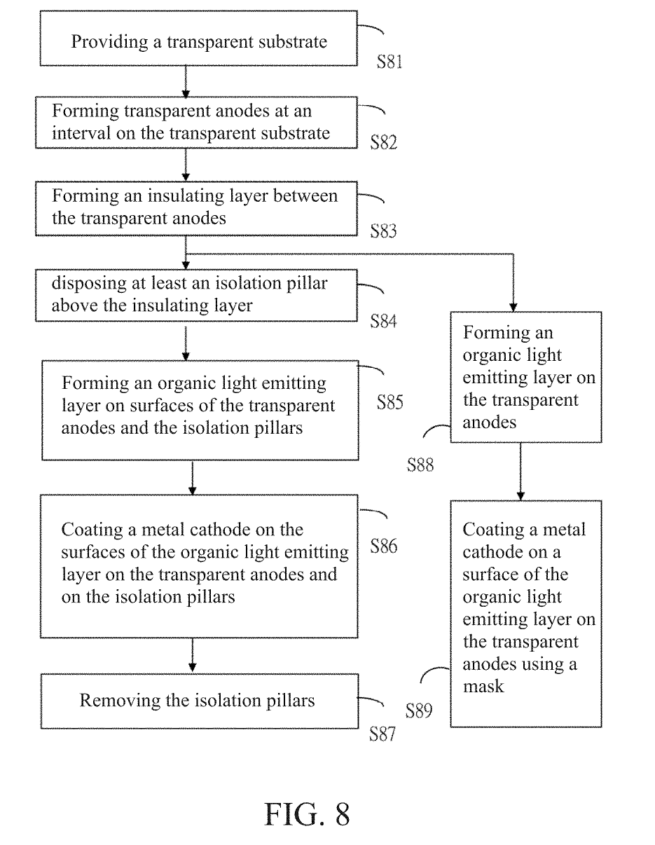

Referring to FIG. 8, a flowchart illustrating a method for manufacturing a transparent OLED in accordance with another embodiment of the present disclosure is shown. The method for manufacturing a transparent OLED includes the following steps. In step S81, a transparent substrate is provided. In step S82, transparent anodes are arranged at an interval on the transparent substrate. In step S83, an insulating layer is formed between the transparent anodes. In step S84, isolation pillars are disposed above the insulating layer. In step S85, an organic light emitting layer is formed on the surfaces of the transparent anodes and the isolation pillars. In step S86, a metal cathode is coated on the surface of the organic light emitting layer on the transparent anodes and on the surface of the organic light emitting layer on the isolation pillars. In step S87, the isolation pillars are removed.

In the above method, the isolation pillars are first disposed and then removed. Therefore, the finished transparent OLED will not have any isolation pillars. In an alternative, after step S83, i.e., after an insulating layer being formed between the transparent anodes, the next step for forming the isolation pillars is skipped, and, instead, an organic light emitting layer is formed on the transparent anodes as shown in step S88. Finally, a metal cathode is formed on the surface of the organic light emitting layer on the transparent anodes using a mask to complete the manufacturing of the transparent OLED, as shown in step S89.

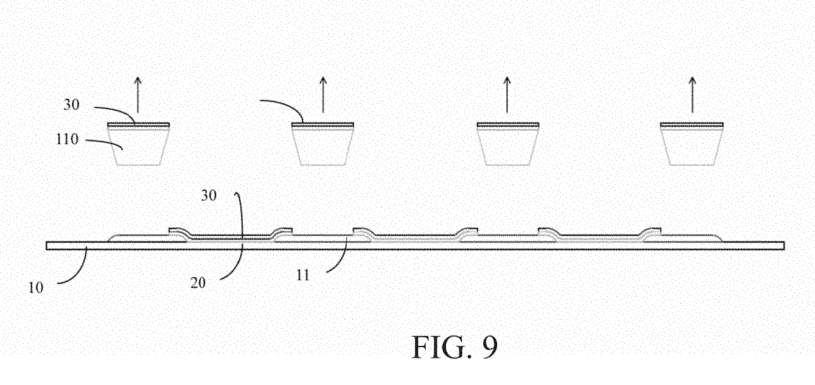

The transparent OLED formed in the above alternative has no isolation pillars. In summary, the metal cathode can be formed on only the surface of the organic light emitting layer on the transparent anodes through the use of mask or by forming and subsequently removing the isolation pillars. As shown in FIG. 9, when the metal cathode 30 is formed, the metal cathode 30 is coated on the surfaces of the organic light emitting layer 20 both on the transparent anodes 10 and the isolation pillars 110. Once the metal cathode 30 is coated, the isolation pillars 110 are removed. The transparent OLED formed has no isolation pillars 110, and has a smaller coating area of the metal cathode 30, thereby increasing the overall light transmittance.

The foregoing descriptions of the detailed embodiments are only illustrated to disclose the features and functions of the present disclosure and not restrictive of the scope of the present disclosure. It should be understood to those in the art that all modifications and variations according to the spirit and principle in the disclosure of the present disclosure should fall within the scope of the appended claims.

What is claimed is:

1. A transparent organic light emitting diode (OLED), comprising:
a transparent substrate;
transparent anodes arranged at an interval on the transparent substrate and bridged by an insulating layer;
an organic light emitting layer coated on surfaces of the transparent anodes; and
a metal cathode coated on a surface of the organic light emitting layer on the transparent anodes.

2. The transparent OLED of claim 1, further comprising at least an isolation pillar provided above the insulating layer.

3. The transparent OLED of claim 2, wherein the organic light emitting layer is further coated on surfaces of the isolation pillars.

4. The transparent OLED of claim 2, wherein at least one of the insulating layer and the isolation pillar is made of a transparent resin.

5. The transparent OLED of claim 4, wherein the transparent resin has a transmittance of 80% or more for visible light having a wavelength in a range of from 400 nm to 800 nm.

6. The transparent OLED of claim 4, wherein the transparent resin is made of poly methyl methacrylate (PMMA), polycarbonate (PC), polystyrene (PS), polyethylene terephthalate (PET or PETE), or a combination thereof.

7. The transparent OLED of claim 2, wherein at least one of the insulating layer and the isolation pillar is made of a semi-transparent resin.

8. The transparent OLED of claim 7, wherein the semi-transparent resin has a transmittance between 50% and 85% for visible light having a wavelength in a range of from 400 nm to 800 nm.

9. The transparent OLED of claim 7, wherein the semi-transparent resin is made of polypropylene (PP), polyamide (PA), or a combination thereof.

10. A method for manufacturing the transparent OLED of claim 1, the method comprising:
providing the transparent substrate;
forming the transparent anodes at an interval on the transparent substrate;
forming the insulating layer between the transparent anodes; and
forming the organic light emitting layer on the surfaces of the transparent anodes.

11. The method of claim 10, further comprising disposing at least an isolation pillar above the insulating layer.

12. The method of claim 11, further comprising forming the organic light emitting layer on surfaces of the isolation pillars.

13. The method of claim 12, further comprising coating the metal cathode on the surface of the organic light emitting layer on the transparent anodes by using a mask.

14. The method of claim 10, further comprising coating the metal cathode on the surface of the organic light emitting layer on the transparent anodes by using a mask.

15. The method of claim 12, further comprising coating the metal cathode on the surfaces of the organic light emitting layer on the transparent anodes and on the isolation pillars.

16. The method of claim 14, further comprising removing the isolation pillars.
